(19) United States
(12) Patent Application Publication
(10) Pub. No.: US 2024/0393145 A1
(43) Pub. Date: Nov. 28, 2024

(54) FIELD DEVICE

(71) Applicant: Endress+Hauser SE+Co. KG, Maulburg (DE)

(72) Inventors: Daniel Kopp, Lörrach (DE); Martin Kropf, Steinen (DE); Alexander Meinhardt, Lörrach (DE); Stefan Rauch, Wehr (DE); Philipp Reichert, Steinen-Hägelberg (DE)

(21) Appl. No.: 18/691,946

(22) PCT Filed: Sep. 5, 2022
(86) PCT No.: PCT/EP2022/074581

§ 371 Date: Mar. 14, 2024

(30) Foreign Application Priority Data
Sep. 14, 2021 (DE) 10 2021 123 664.9

(51) Int. Cl. G01D 11/24

(52) U.S. Cl. CPC G01D 11/245

(57) ABSTRACT

A robustly designed field device for determining a process variable comprises a plastics-based housing having an interior and a passageway that adjoins the interior along a device axis; an enclosure of an electrically conductive material secured in the interior and formed to surround a first electronics module at least radially relative to the device axis; a measuring device neck that is secured to the enclosure such that it is oriented in the direction of the device axis and in communication with the passageway; and a sensor for determining the process variable and arranged at a housing far end region of the measuring device neck. As a result of this construction, a wear susceptible securement between the plastics-based housing and the metal measuring device neck can be avoided.

### FIELD DEVICE

The invention relates to a robustly embodied field device.

In process automation technology, field devices are often applied, which serve for registering, or influencing, certain process variables. For registering a process variable, a field device includes, depending on type, chosen electronic components for putting the relevant measuring principle into practice. Depending on design, the field device type can, thus, be used, for example, for measuring a fill level, a flow, a pressure, a temperature, a pH value and/or a conductivity. A wide variety of such field device types are manufactured and sold by the Endress+Hauser group of firms.

The electronic modules of a field device are often accommodated in a metal housing, which serves as a Faraday cage to protect the modules. The metal housing is appropriately grounded. However, there are applications, where a non-metallic housing is advantageous, or required. Thus, for example, field devices, which are applied in corrosive environments, such as, for instance, ocean-near sites as well as in processes with acidic or alkaline media, preferably make use of a plastics-based housing. The electronic modules are, in such cases, protected by an additional, electrically conductive enclosure, which functions as a Faraday cage and is arranged together with the electronic modules within the plastics-based housing. A corresponding field device, is described, for example, in DE 10 2015 107 306 A1.

Independently of field device type, the sensor is, as a function of the principle on which it operates, brought in direct contact with the interior of the process container. Above all for explosion protection, however, often a spatial isolation between the active modules, thus, modules supplied with electrical current, and the predominantly passive sensor is required. For this, the field device can include a measuring device neck, via which the sensor is connected with the housing, in which, especially temperature sensitive, electronic modules of the fill level measuring device, such as interface modules for communication with the outside, are accommodated. In such case, depending on requirements, an appropriate explosion protective barrier is arranged in the measuring device neck. Additionally or alternatively to explosion protection requirements, the measuring device neck must, in given cases, fulfill other protective functions. Thus, depending on application, high temperatures, high pressure or dangerous gases can be present in the interior of the container. Therefore, the measuring device neck must, depending on application, also function as a pressure seal, temperature barrier and/or media seal.

In the case of a plastics-based housing, its assembly with the measuring device neck can present problems, since the stability of a possible screw thread securement with the housing can, in given cases, be lost, even after just a few screw-on cycles, especially when the measuring device neck involves a hard material, such as steel. An object of the invention, therefore, is to provide a more robust field device.

The object is achieved by a field device, comprising:
an electrically insulating housing, having
   an interior, and
   a passageway, which adjoins the interior along a device axis,
an enclosure composed of an electrically conductive material, securable in the interior, and formed to surround a first electronics module at least radially relative to the device axis,
a measuring device neck, which is secured to the enclosure in such a manner that it is oriented in the direction of the device axis and in communication with the passageway of the housing, and
a sensor for determining the process variable and arranged at a housing far, end region of the measuring device neck.

Advantageously, the solution of the invention provides that the housing is only indirectly secured to the measuring device neck, namely via the enclosure. In this way, a wear susceptible, plastic, screw thread on the housing can be avoided. Nevertheless, it is possible based on this design to encapsulate the interior hermetically sealed, thus, air tightly, for example, for purposes of explosion protection, when the housing is correspondingly designed, and when the passageway to the measuring device neck is correspondingly sealed.

In the context of the invention, it is constructively not fixedly prescribed, how the enclosure, including the housing, is secured to the measuring device neck. For example, the measuring device neck can be secured to the enclosure by means of a screw thread connection oriented along the device axis, or by means of a plug-in connection. In such case, the invention enables that such a screw thread connection is designed with a stable M60 screw thread or smaller, since the plastic housing is not involved.

Moreover, it is according to the invention not fixedly prescribed, how the housing is mechanically secured to the enclosure. For example, in the enclosure and in the housing, corresponding, first screw openings can be provided, in order to secure the enclosure in the interior by means of a first screwed, or bolted, connection. In such case, it is not critical in the design of the field device of the invention, how stable the securing of the housing to the enclosure should be. Thus, the mechanical loadability of the first screwed connection can be significantly lower than the securing of the measuring device neck to the enclosure.

Regarding EMC aspects, it is, in given cases, required that the electronics module be surrounded by the enclosure with respect to the device axis not only radially, but also axially. In a further development of the enclosure, such can, for this, with respect to the device axis, nevertheless include a measuring device neck far, open end region, which is capped by a circuit board with possible additional electronic modules. In this way, also with space saving utilization of the housing interior, possible EMC specifications can be fulfilled.

In the construction of the invention, the plastic housing behaves relative to the securement to the measuring device neck with the help of the enclosure as a metal housing, such that the field device can be made by means of method steps as follows:
arranging the first electronics module within the enclosure,
subsequent or preceding securing of the enclosure in the interior, and
securing the enclosure to the measuring device neck, such that the measuring device neck is arranged in the passageway of the housing.

The invention will now be explained in greater detail based on the appended drawing, the figures of which show as follows:

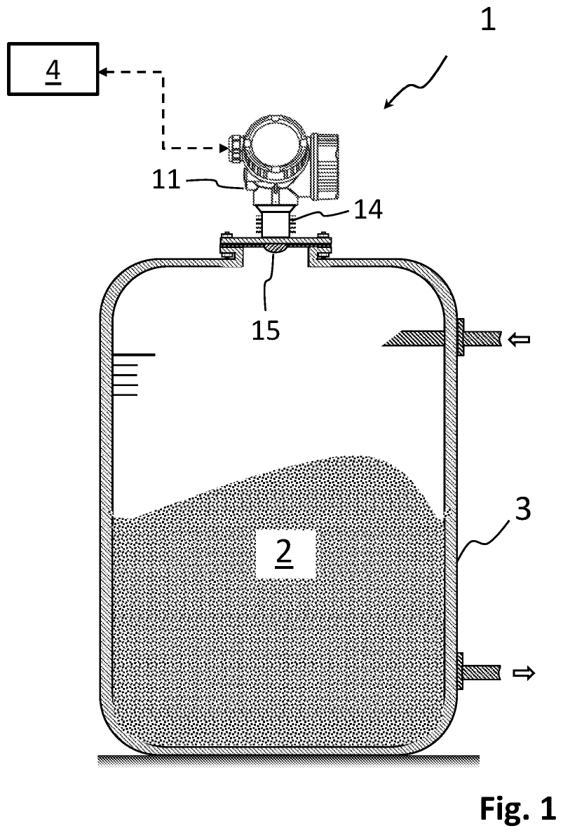

FIG. 1 a field device for determining a process variable in a container,

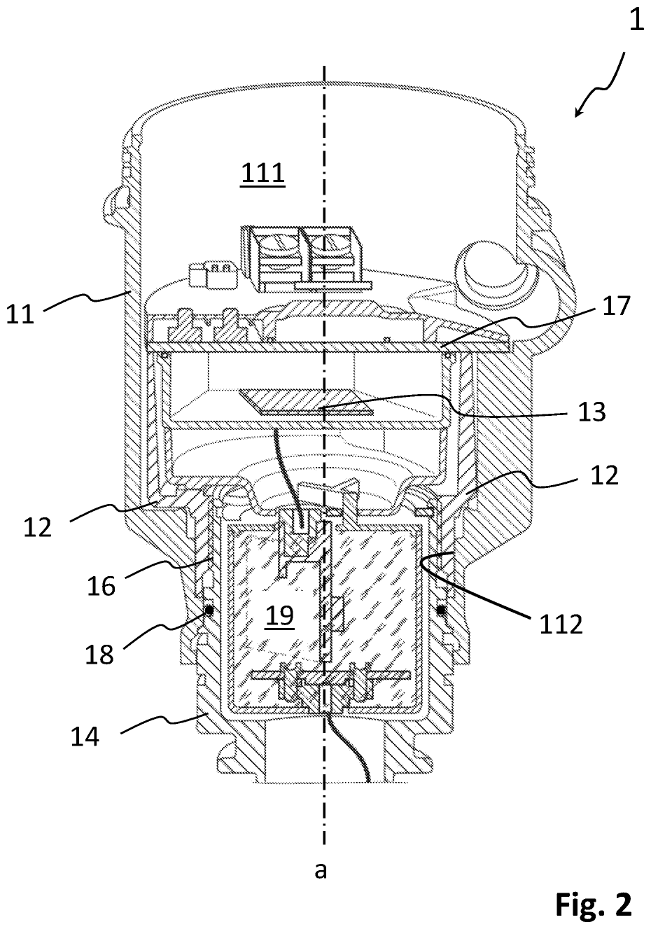

FIG. 2 a sectional view of the field device of the invention in the region of the enclosure, and

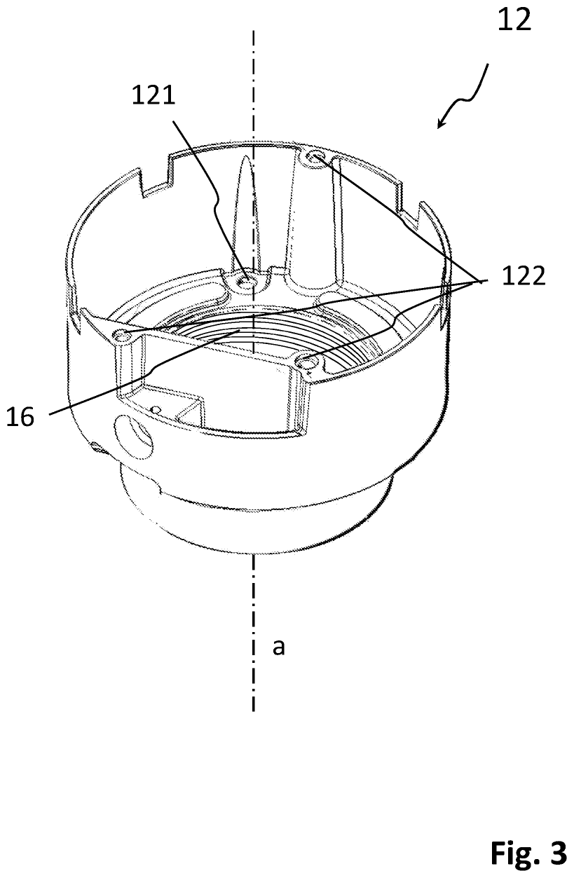

FIG. 3 a detail view of the enclosure.

For an understanding of the invention in principle, FIG. 1 shows a process container 3 of a process plant, wherein the container 3 serves, for example, to provide a chamber for a chemical, or biological, reaction, or for storing an educt 2. In such case, the container 3 can, depending on type of fill substance 2 and depending on field of application, be even greater than 100 m high. Depending on the process, the process variable to be determined within the container 3 is, for example, a fill level, a limit level, a temperature, a pH value or a conductivity. Also the conditions in the container 3 depend on the type of fill substance 2 and the field of application. Thus, in the case of exothermic reactions, for example, excessive temperature- and pressure loading can occur. In the case of dust containing or ignitable materials, corresponding explosion protection requirements must be maintained in the interior of the container.

In order to be able to determine the process variable of interest, a field device 1 having a relevant sensor 15 is placed in a known, installed position on the container 3. In such case, the field device 1 is secured, or oriented, in such a manner at an opening of the container 3 that only the sensor 15 has access to the container 3 via a container opening. The additional modules 13, 19 of the field device 1 are accommodated correspondingly corrosion- and weather resistantly outside of the container 3 in a plastics-based housing 11 of the field device 1.

As shown in FIGS. 1 and 2, there can be arranged in the housing 11 of the field device 1 in the form of an electronics module 13, for example, an interface, which connects the field device 1 via a corresponding protocol, such as, for instance, “4-20 mA”, “PROFIBUS”, “HART”, “WLAN” or “Ethernet”, to a superordinated unit 4, such as e.g. a local process control system or a decentralized server system. In this way, the measured process variable can be transmitted, for example, in order, in given cases, to control in- or outflows of the container 3. It is possible, however, also to communicate other information concerning the general operating state of the field device 1. The separate provisioning of the interfaces as independent module 13 has the advantage that such module 13 can be used in other field device types. Alternatively to an interface, the module 13 shown in FIG. 2 can, however, also have any other function.

In the embodiment shown in FIG. 2, the housing 11 of the field device 1 has an interior 111, which is cylindrical about a device axis a. In order that the modules 13 arranged in the interior 111 are protected from an EMC (“electromagnetic compatibility”) point of view, there is supplementally arranged an enclosure 12, which surrounds the one or more electronic modules 13 radially relative to the device axis a. Because the enclosure 12 is made of an electrically conductive material, the enclosure 12 acts as a Faraday cage. Axially in its sensor-far end region, the enclosure 12 is not closed, but, instead, has a circularly round, open, end region. This end region is closed in the illustrated embodiment by a circuit board 17 arranged orthogonally to the device axis a. In this way, the module 13 is EMC-protected also at the sensor-far end region of the enclosure 12. In such case, for example, connections for the external contacting of the field device 1 can be placed on the circuit board 17. Advantageous in this respect is that the integration density of the components 12, 13, 17 within the housing 11 is increased, such that the interior 111 can, as a whole, be designed compactly. Alternatively to the illustrated form of embodiment, it is also an option that the enclosure 12 can be closed by an, in given cases, integrated, likewise conductive, cover instead of the circuit board 17.

Because the field device 1 with exception of the sensor 15 is arranged outside of the container 3, on the one hand, the explosion-protection within the container 3 is increased. On the other hand, temperature- and pressure-sensitive components 13, 17 in the interior 111 of the field device housing 11 are protected against temperature- and pressure loading from the container interior. To this end, the housing 11 is, moreover, such as especially shown in FIG. 2, spaced from the sensor 15, and from the container opening, by a separate housing part in the form of a measuring device neck 14. In such case, the measuring device neck 14 is also oriented along the device axis a, such that the sensor side end region of the measuring device neck 14 in the secured state of the field device 1 is directed into the interior of the container 3. The sensor-far end region of the measuring device neck 14 opens correspondingly into a passageway 112 in the housing floor of the housing 11, such that the sensor 15 can be contacted via the measuring device neck 14 and the passageway 112 electrically with the electronics module 13 in the interior 111 of the housing 11.

As shown in FIG. 2, when required, a possible second electronics module 19 can also be arranged directly in the measuring device neck 14, when, for example, short high frequency signal paths, or a sensor-near signal-evaluation is required and the second module 19 is correspondingly stably encapsulated. As a result of this outwards placement of the second module 19, moreover, space consumption in the housing interior 111 can be further minimized. In such case, the measuring device neck 14 can, in the case of metal construction, additionally, have cooling fins for thermal decoupling, such as shown in FIGS. 1 and 2.

Since the field device 1, as shown in FIG. 1, is secured to the container 3 via the measuring device neck 14, the housing 11, including the components 12, 13, 17 located in the interior 111, must be secured as stably as possible to the measuring device neck 14, for example, by means of a M60-screw thread connection 16. As shown in FIG. 2, the measuring device neck 14 includes, for this, a corresponding outer screw thread at the sensor-far end region at the height of the passageway 112, wherein the screw thread connection 16 is oriented, in turn, along the device axis a.

According to the invention, the corresponding internal screw thread of the screw thread connection 16 is not located in the plastic of the passageway 112. Rather, the metal enclosure 12 includes in the region of the passageway 112 a corresponding internal screw thread for the outer screw thread of the measuring device neck 14. Since the enclosure 12 is, in turn, secured in the interior 111 of the housing 11, such including the shielded electronics module 13 is, thus, connected mechanically with the measuring device neck 14 indirectly via the enclosure 12. In this way, the maximum possible number of screwing cycles of the screw thread connection 16 is not limited by the plastic of the housing 11. This becomes noticeable especially when the housing 11 needs, for example, because of service- and maintenance tasks, periodically to be screwed off.

In the case of the embodiment of the field device 1 of the invention shown in FIG. 2, the housing 11 is sealed to the measuring device neck 14 at the height of the passageway 112 by a sealing ring 18. In this way, the interior 111 of the housing 11 is outwardly hermetically sealed when also the housing 11 as such is hermetically sealed. This contributes, in turn, to the explosion resistant design of the field device 1.

The internal screw thread of the screw thread connection 16 in the enclosure 12 is shown in detail in FIG. 3. From this detail view, it is, moreover, evident, how the enclosure 12 can be secured in the interior 111 of the housing 11. For this, first screw openings 121 are placed in a step of the enclosure 12, where the enclosure 12 along the device axis a toward the measuring device neck 14 is correspondingly reduced in diameter. By means of the resulting first screw connections near the passageway 112, the enclosure 12 can be secured in the housing 11. Also the circuit board 17 can be secured by means of at least a second screwed connection to the enclosure 12. As shown in FIG. 3, the enclosure 12 includes for this at its axially sensor-far opening three screw openings 122, which are oriented in parallel with device axis a.

### LIST OF REFERENCE CHARACTERS

1 field device
2 fill substance
3 container
4 superordinated unit
11 housing
12 enclosure
13 electronics module
14 measuring device neck
15 sensor
16 screw thread connection
17 circuit board
18 sealing ring
19 second electronics module
111 interior of the housing
112 passageway
121 first screw openings
122 second screw openings
a device axis

1-7. (canceled)

8. A field device for determining a process variable, comprising:
an electrically insulating housing having an interior and a passageway that adjoins the interior along a device axis;
an enclosure composed of an electrically conductive material, wherein the enclosure is secured in the interior and is formed to surround a first electronics module at least radially relative to the device axis;
a measuring device neck that is secured to the enclosure in such a manner that the measuring device neck is oriented in a direction of the device axis and in communication with the passageway of the electrically insulating housing; and
a sensor for determining the process variable, wherein the sensor is arranged at a housing far end region of the measuring device neck.

9. The field device as claimed in claim 8, wherein the measuring device neck is secured to the enclosure by a screw thread connection that is oriented along the device axis, or by a plug-in connection.

10. The field device as claimed in claim 9, wherein the screw thread connection is designed at most with an M60 screw thread.

11. The field device as claimed in claim 8, wherein, in the enclosure and in the housing, corresponding first screw openings are provided to secure the enclosure in the interior via a first screwed, or bolted, connection.

12. The field device as claimed in claim 8, wherein the enclosure with respect to device axis includes a measuring device neck far, open end region, and wherein the open end region of the enclosure is capped by a circuit board.

13. The field device as claimed in claim 8, wherein the housing is designed in such a manner and the passageway is sealed in such a manner that the interior is hermetically sealed.

14. A method for producing a field device, comprising:
providing:
an electrically insulating housing having an interior and a passageway that adjoins the interior along a device axis;
an enclosure composed of an electrically conductive material;
a first electronics module; and
a measuring device neck;
arranging the first electronics module within the enclosure;
securing the enclosure in the interior of the electrically insulating housing; and
securing the measuring device neck to the enclosure such that the measuring device neck is arranged in the passageway of the housing.
